(19) United States
(12) Patent Application Publication
(10) Pub. No.: US 2015/0235864 A1
(43) Pub. Date: Aug. 20, 2015

(54) METHOD FOR PROCESSING A LAYER AND A METHOD FOR MANUFACTURING AN ELECTRONIC DEVICE

(71) Applicant: Infineon Technologies AG, Neubiberg (DE)

(72) Inventors: Mirko Vogt, Dresden (DE); Felix Braun, Dresden (DE); Jens Schneider, Moritzburg (DE); Bee Kim Hong, Dresden (DE); Matthias Schmeide, Langebrueck (DE)

(73) Assignee: Infineon Technologies AG, Neubiberg (DE)

(21) Appl. No.: 14/181,751

(22) Filed: Feb. 17, 2014

(51) Int. Cl. H01L 21/311; H01L 21/266; H01L 21/3213

(52) U.S. Cl. CPC H01L 21/31144; H01L 21/32139; H01L 21/266

(57) ABSTRACT

A method for processing a layer may include: providing a patterned carbon layer over a layer or over a carrier; and carrying out an ion implantation through the patterned carbon layer into the layer or into the carrier.

### TECHNICAL FIELD

Various embodiments relate generally to a method for processing a layer and a method for manufacturing an electronic device.

### BACKGROUND

in general, various semiconductor processes may be utilized for doping a carrier or a wafer. One method for doping carrier may be ion implantation, wherein ions are implanted into the carrier material due to their high kinetic energy. Further, a mask may be applied to protect specific areas from the implantation of ions and to allow ion implantation in other areas, e.g. to form doped regions in the carrier material. Manufacturing electronic devices or integrated circuits may generally include one or more ion implantation processes, e.g. to generate the desired doped regions in the carrier or in a layer over the carrier. Generally, performing an on implantation may require protecting one or more regions of a layer or a carrier from being penetrated by the ions, and therefore, the respectively utilized mask layer may be adapted in the respective thickness, wherein the mask layer may have a larger thickness for shadowing ions having a higher energy.

### SUMMARY

A method for processing a layer may include: providing a patterned carbon layer over a layer; and carrying out an ion implantation through the patterned carbon layer into the layer.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a schematic flow diagram of a method for processing a layer or a carrier, according to various embodiments;

FIG. 1B shows a schematic flow diagram of a method for manufacturing an electronic device, according to various embodiments;

FIG. 1C shows a schematic flow diagram of a method, according to various embodiments;

FIGS. 2A to 2I respectively show a schematic side view or cross sectional view of a layer or a carrier during the processing or during the manufacture, according to various embodiments;

FIG. 3 shows a schematic side view or cross sectional view of a layer or a carrier during the processing or during the manufacture, according to various embodiments;

FIG. 4 shows a schematic side view or cross sectional view of a layer or a carrier during the processing or during the manufacture, according to various embodiments;

FIG. 5 shows an electron microscopy image of a commonly used resist mask layer after an ion implantation process has been carried out; and

FIG. 6 shows an electron microscopy image of a patterned carbon mask layer during or after the processing described herein, according to various embodiments.

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

The term “lateral” used with regards to the “lateral” extension of a structure (or of a carrier) or “laterally” surrounding, may be used herein to mean an extension along a direction parallel to a surface of a carrier. That means that a surface of a carrier (e.g. a surface of a substrate, or a surface of a wafer) may serve as reference, commonly referred to as the main processing surface of a wafer (or the main processing surface of another type of carrier). Further, the term “width” used with regards to a “width” of a structure (or of a structure element) may be used herein to mean the lateral extension of a structure. Further, the term “height” used with regards to a height of a structure (or of a structure element), may be used herein to mean an extension of a structure along a direction perpendicular to the surface of a carrier (e.g. perpendicular to the main processing surface of a carrier).

According to various embodiments, the term layer may be used herein to mean a layer, a film, a thin film, a cover layer, a barrier layer, and the like, and further, term layer may be used herein to mean a substrate, a carrier, a wafer, a solid body, and the like or at least a part of a substrate, a carrier, a wafer, or a solid body. Further, a layer may also cover at least partially a substrate, a carrier, a wafer, or a solid body or the layer may be disposed over a substrate, a carrier, a wafer, or a solid body.

According to various embodiments, an ion implantation process may be performed using an ion implantation system (or an ion implantation device, e.g. an implanter), wherein the ion implantation system may include an ion source providing the ions of a material and an acceleration system accelerating the provided ions via an electrical field (or electromagnetic field) such that an ion beam or a directed ion current may be provided. The ion beam or the ion current may be guided onto a solid body (e.g. a carrier, a wafer, or a layer) such that the ions impact into the solid body and remain (stop, e.g. via electronic stopping and/or nuclear stopping) within the solid material of the solid body. The energy of the ions, e.g. the kinetic energy, as referred to herein, may be defined by the acceleration of the ions within the acceleration system of the ion implantation system. An ion implantation process may be used to change or adapt the physical, chemical, or electrical properties of the solid, e.g. the chemical composition (e.g. forming silicon oxide within a silicon wafer) or e.g. doping a material (e.g. doping a semiconducting material of a wafer or of a layer) to change the electrical conductivity of the material.

The projected range (e.g. the average distance of the implanted (stopped) ions from the surface of the body) may depend on the energy of the implanted ions (e.g. from the mass of the ions and the acceleration of the ions). Since the ions may straggle during traveling through the solid material until the ions stop, the respective implant profile may include a Gaussian distribution, a Pearson (e.g. type IV) distribution or a double Pearson distribution.

Implanting ions into a solid may cause a structural change or damage of the crystal structure of the solid. The damaging of the solid material may be cured by a subsequently performed thermal annealing process. Therefore, a rapid thermal processing may be applied to the solid material (e.g. to a silicon wafer) after the ion implantation of dopants (e.g. phosphorus (P), arsenic (As) or boron (B)) has been carried out. Thereby, vacancies being generated at the annealing temperature (e.g. at a temperature larger than about 1000° C., e.g. larger than about 1200° C.) may facilitate the movement of dopants from interstitial lattice sites to substitutional lattice sites. Further, the amorphization damage from the ion implantation process may be cured due to recrystallization processes. The rapid thermal processing, e.g. within one second or within a couple of seconds, may minimize undesired chemical diffusion of the dopants within the solid material. Illustratively, the thermal processing may be used to either exclusively cure the crystal structure and let the ion distribution of the implanted ions unchanged, or to both, cure the crystal structure and change the ion distribution (doping profile) of the implanted ions.

For implanting ions into a material the ions may be accelerated to have high kinetic energies, e.g. energies larger than about 1 MeV, and masking materials may be utilized, wherein a mask layer including the masking material may be provided having a large layer thickness, e.g. larger than about several micrometers. In commonly used ion implantation processes, a resists layer having a thickness of equal to or larger than about 6 μm may be utilized for a 5 MeV ion implantation.

Various embodiments are based on the understanding that due to the larger thickness of the resist layers, which may be necessary for high energy implants, the lateral resolution and/or the stability of the resist layer may be limited. Illustratively, the need of high energy ion implants may arise in semiconductor technology, wherein the persistently decreasing feature size may be limited by the commonly used masking materials for ion implantation. In commonly used processes, wherein a resist is used as masking material, a 5 MeV implant may require a resist layer having a thickness larger than about 5 μm, e.g. a resist layer having a thickness of about 6 μm, wherein the resist with this thickness may be limited during patterning to an aspect ratio of three which may result in a maximal possible lateral resolution (critical dimension (CD)) of about 2 μm. Illustratively, commonly applied ion implantation processes using resists as masking material may be limited to a lateral feature size or CD of equal to or larger than 2 μm, wherein there may be desired applications having a smaller feature size or requiring a smaller CD during processing.

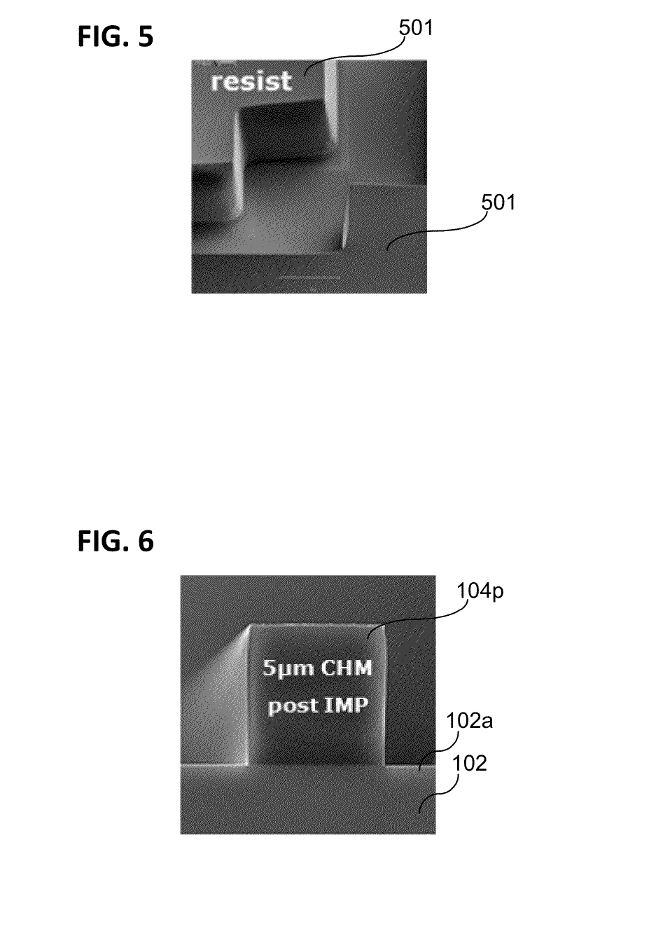

Besides this, the mechanical stability, e.g. the adhesion on the underlying carrier, of the necessarily thick resist implantation mask may be limited or may cause problems during processing, e.g. the resist implantation mask may peel off due to the energy input into the resist during the high energy ion implantation. Further, the resist implantation mask may crack or the resist implantation mask may be deformed during the high energy ion implantation, as illustrated in FIG. 5 in an example for a 6.5 μm thick resist implantation mask after a high energy implantation (5 MeV).

According to various embodiments, it was recognized, that the ion implantation process may cause a mechanical stress and/or strain within the resist implantation mask such that the resist implantation mask may bend or deform itself and/or peal of the carrier. Despite various possibilities which can be utilized for improving the adhesion and/or stability of the resist layer, using a resist as masking layer for the high energy ion implantation may be limited in the feature size, e.g. to about 2 μm. Further, such thick resist layers may have a non-sufficient homogeneity of the resist layer thickness, surface density, and/or morphology. Further, the highly specifically designed resists for high energy ion implantation may be too expensive to be used as such thick layers. Further, problems may arise regarding the removal of the resist after the ion implantation has been carried out. Further, using a particular adhesion promoter may be too expensive as well, and the lateral CD may not be significantly reduced due to generally occurring problems.

According to various embodiments, a carbon hard mask layer may be utilized as masking layer or blocking layer during an ion implantation process, wherein the carbon hard mask layer may be patterned, such that the processable feature size or the lateral critical dimension CD may not be limited due to the realizable aspect ratio of the resist.

According to various embodiments, a carbon layer may be utilized as hard mask layer or carbon may be used as masking material, since the achievable aspect ratio using carbon as a hard mask for high energy ion implantation may be equal to or larger than about 7. Further, a carbon hard mask layer may be easily selectively removed from the underlying carrier, e.g. from a semiconductor carrier or wafer, using a plasma cleaning via oxygen or a so-called ashing process (the carbon may be removed via oxidizing the carbon to gaseous carbon oxide and/or carbon dioxide). Illustratively, also a thick carbon layer, e.g. having a thickness of equal to or larger than about 5 μm may be patterned such that an aspect ratio of the mask layer structures may be equal to or larger than about 7. This may significantly reduce the processable feature size or lateral critical dimension during a high energy ion implantation process.

Further, a carbon hard mask layer may be formed having a higher density than the commonly used resist layers, e.g. a density of larger than about 1.5 g/cm³ or a density in the range from about 1.5 g/cm³ to about 3.5 g/cm³. Since the carbon hard mask layer may have a density larger than the density of a resist layer, a thinner carbon hard mask layer may be used for masking the carrier compared to resist materials, since the ion stopping mechanisms may depend on the density of the material. This may further reduce the feature size or lateral critical dimension being processable while applying a high energy ion implantation (e.g. larger than about 1 MeV).

According to various embodiments, carbon deposited via plasma enhanced chemical vapor deposition (PECVD carbon) may be utilized as masking material for a (e.g. high energy) ion implantation process. Therefore, the feature size or lateral critical dimension may be reduced compared to commonly used resist layers, while an enhanced processability may be provided (e.g. due to an enhanced mechanical stability, removability, or a larger processable aspect ratio or due to being not limited in the layer thickness) compared to commonly used resist layers. Illustratively, it was recognized, that using a carbon hard mask layer for ion implantation may circumvent the typically occurring problems and limitations caused by a resist layer (a soft mask), while having no substantial disadvantage referring to the selective removability or the forming and/or pattering of the carbon hard mask layer. A carbon hard mask layer may be removed easily form the carrier via a plasma cleaning or ashing, compared to other hard mask material like silicon oxide (SiO₂), silicon nitride (Si₃N₄), titanium nitride, a silicide and/or the like.

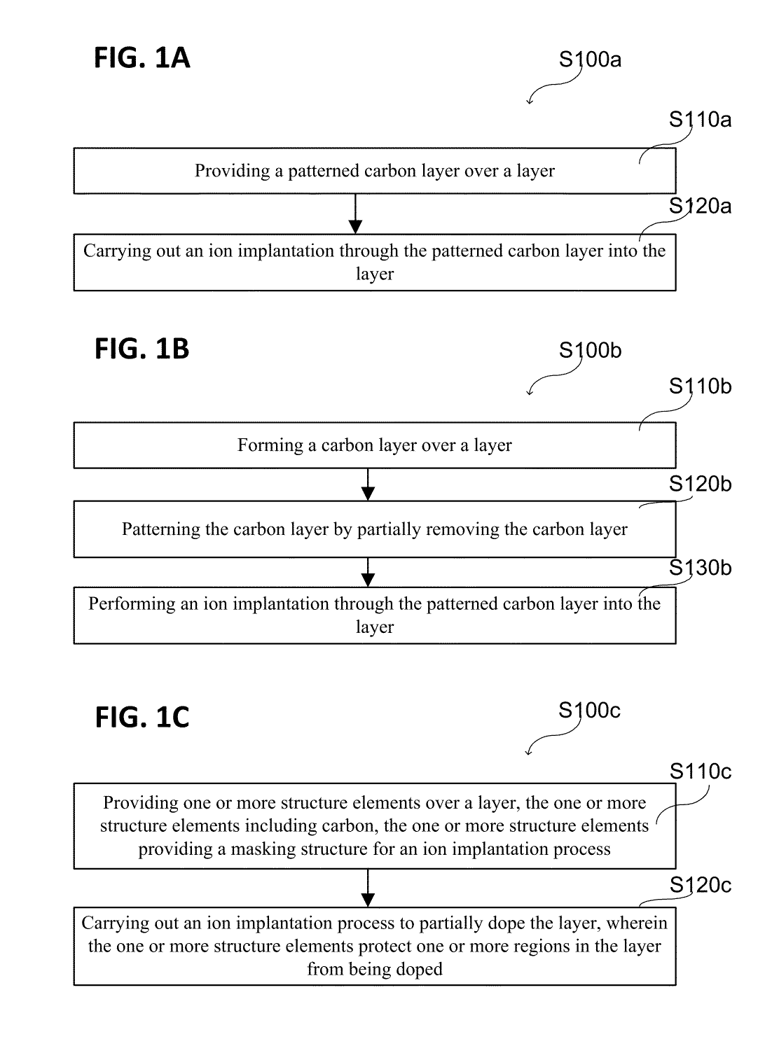

FIG. 1A shows a schematic flow diagram of a method S100a for processing a layer, according to various embodiments, wherein the method S100a may include: in S110a, providing a patterned carbon layer over a layer; and, in S120a, carrying out an ion implantation through the patterned carbon layer into the layer. Illustratively, the patterned carbon layer may provide a hard mask layer or a hard mask structure over the layer for an ion implantation process. The layer may be or may include silicon (e.g. amorphous silicon (a-Si) or polycrystalline silicon (poly-Si)) or any other semiconducting material. The a-Si layer or the poly-Si layer may be doped via ion implantation, e.g. thereby influencing the electrical conductivity of the layer or the chemical properties of the layer, e.g. the etching rate for wet etching. According to various embodiments, the layer may include an oxide, e.g. transparent conductive oxides, wherein the oxide layer may be doped via ion implantation. The layer may also represent a carrier, e.g. a wafer or any other type of carrier being used in semiconductor industry, e.g. a substrate, a foil, or a tape.

In other words, a method for processing a carrier may be provided herein, according to various embodiments, wherein the method for processing a carrier may include: in analogy to S110a of method S100a, providing a patterned carbon layer over a carrier; and, in analogy to S120a of method S100a, carrying out an ion implantation through the patterned carbon layer into the carrier.

Alternatively, as illustrated in FIG. 1B in a schematic flow diagram, a method S100b for manufacturing an electronic device or an electronic component may include: in S110b, forming a carbon layer over a layer or over a carrier; in S120b, patterning the carbon layer by partially removing the carbon layer; and, in S130b, performing an ion implantation through the patterned carbon layer into the layer or into the carrier. Illustratively, the patterned carbon layer may provide a hard mask layer or a mask structure over the layer or over a carrier for an ion implantation process.

According to various embodiments, as shown in FIG. 1C, a method S100c (e.g. a method for processing a carrier, a method for processing a layer, a method for manufacturing an electronic device or an electronic component, a semiconductor processing) may include: in S110c, providing one or more structure elements over a layer and/or carrier, the one or more structure elements including carbon, the one or more structure elements providing a masking structure for an ion implantation process; and, in S120c, carrying out an ion implantation process to partially dope the layer and/or the carrier, wherein the one or more structure elements protect one or more regions in the layer or in the carrier from being doped.

According to various embodiments, the term doping as referred to herein, may include implanting a first material (a first sort of ions) into a second material of a layer or a carrier, wherein the doping with the first material may change the electronic properties of the second material and/or wherein the doping with the first material may change the chemical properties (e.g. the composition) of the second material (e.g. at least in one or more regions of the second material).

According to various embodiments, the ion implantation may include implanting at least one first material (ions) from the following group of materials into a second material, e.g. into a layer or into a carrier, the group consisting of: boron (B), aluminum (Al), gallium (Ga), germanium (Ge), indium (In), carbon (C), nitrogen (N), oxygen (O), phosphorous (P), sulfur (S), arsenic (As), selenium (Se), antimony (Sb), tellurium (Te), or any other material which can be offered as accelerated ions in an implanter.

According to various embodiments, ion implantation (e.g. the method S100a, S100b, S100c) may be applied to change the physical properties of a material by adding dopant material, wherein the key aspects may be the electronic properties of the doped material (e.g. specific electrical conductivity, charge carrier concentration, charge carrier mobility, electronic band structure). Ion implantation may be used for doping a material, e.g. to provide an electron doped material, so called n-type (negative-type) doped material and/or hole doped material, so called p-type (positive type) doped material.

According to various embodiments, the penetration depth and the distribution of implanted ions in a carrier may depend on the stopping mechanism (the interaction of the ions with the solid state material) and may be varied by varying the kinetic energy of the ions. Other parameters, which may be varied, are the dose (or doping material concentration) and the angle between the surface of the solid state material to be doped and the propagation direction of the ions during an implantation process. According to various embodiments, after implanting ions a thermal annealing process may be carried out to recover the crystal structure from ion damages. After implanting ions a thermal annealing process may be carried out (e.g. a low temperature annealing to recover the crystal structure but preventing a substantial contribution to the diffusion of the dopant material). According to various embodiments, a low temperature annealing may be used to provide more confined doped regions in a carrier.

According to various embodiments, ion implantation (e.g. the method S100a, S100b, S100c) may be applied to change the chemical properties of the layer material or carrier material by adding (implanting) another material different from the layer material or carrier material, for example within a local SIMOX process (Separation by IMplantation of Oxygen), wherein an oxygen ion beam may be used to implant oxygen ions into a silicon layer or silicon carrier, followed by high temperature annealing to form one or more buried silicon oxide regions.

According to various embodiments, the carbon mask layer may be formed having a respective layer thickness to ensure a masking of the layer or carrier below the carbon mask layer. Illustratively, the layer thickness of the carbon mask layer may be larger than the respective penetration depth of the ions into the carbon mask layer, which may depend on the used ions (on the mass of used the ions) and/or on the energy of the ions provide by the implanter.

According to various embodiments, a hard mask (an additional patterned hard mask layer) may be formed over the carbon mask layer, to enable the patterning of the carbon mask layer via a carbon etch process (e.g. an anisotropic etch process). The additional hard mask used for patterning the carbon mask layer may include for example amorphous silicon (a-Si), silicon oxynitride (SiON), silicon oxide (SiO, SiO₂), and/or silicon nitride (SiN). Further, the additional hard mask used for patterning the carbon mask layer may include any other material being suitable for providing a hard mask, as used in semiconductor industry. The additional hard mask may be formed via a chemical vapor deposition process (CVD), e.g. via plasma enhanced chemical vapor deposition (PECVD). The additional hard mask or the additional hard mask layer may be selected to be selectively removable from the layer and/or the carrier.

According to various embodiments, the layer and/or the carrier may include a surface layer of a surface material or e.g. a layer stack. For example, a silicon layer or a silicon carrier may include a silicon oxide surface layer, wherein in this case the additional hard mask may include a-Si, such that the additional hard mask may be easily selectively removable. Further, the carbon layer may be easily patterned due to the high selectivity of the carbon layer etching with respect to the a-Si of the additional hard mask. Therefore, the additional hard mask layer may have a small thickness (e.g. in the range from about 10 nm to about 100 nm) compared to the thickness of the carbon layer (e.g. in the range from about 3 μm to about 10 μm).

According to various embodiments, since the additional hard mask layer may be many times thinner than carbon layer, the additional hard mask (e.g. a patterned a-Si layer) may be patterned via a soft mask (a resist) with a smaller feature size than it would be possible for the carbon layer, if the carbon layer would be directly patterned using a soft mask. The additional hard mask (e.g. a patterned a-Si layer) may be etched or patterned using a standard lithographic process. The carbon layer may be etched or patterned via the additional hard mask (e.g. a patterned a-Si layer). The patterned carbon layer (and optionally the remaining patterned hard mask over the patterned carbon layer) may provide the mask for the ion implantation. The additional hard mask (e.g. a patterned a-Si layer) may be selectively removed with regard to the layer and/or the carrier. The patterned carbon layer may be removed via ashing (oxidizing the carbon to gaseous carbon oxide) or etching. The layer and/or the carrier may be subjected to a cleaning process.

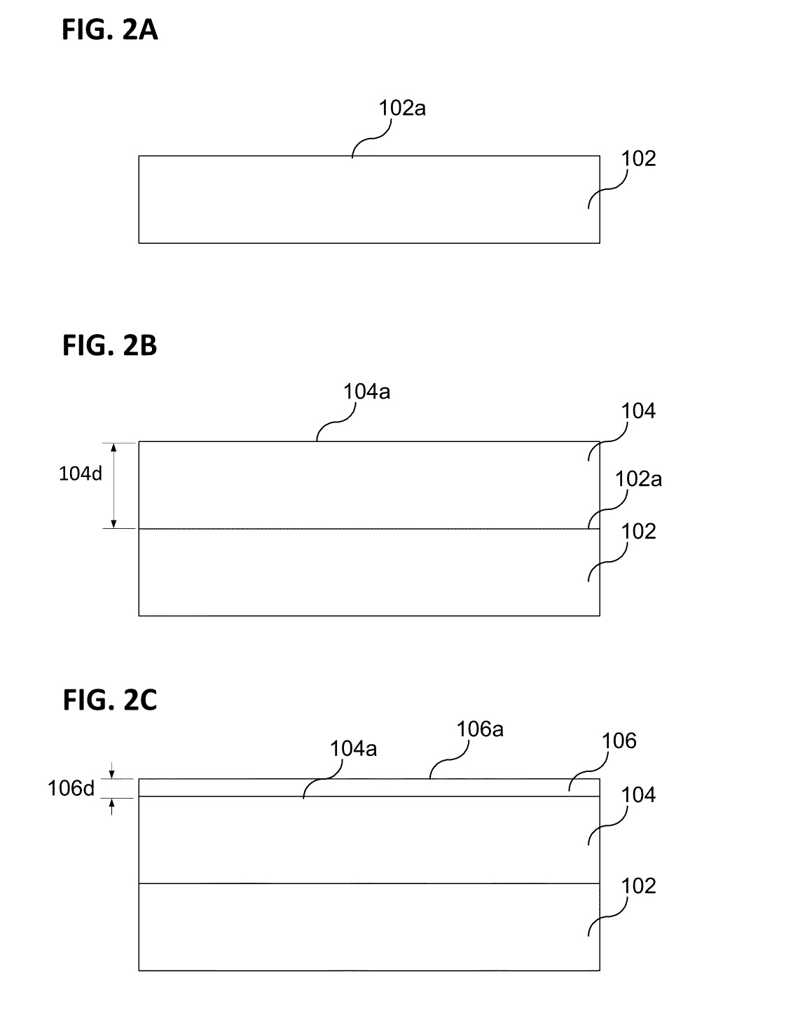

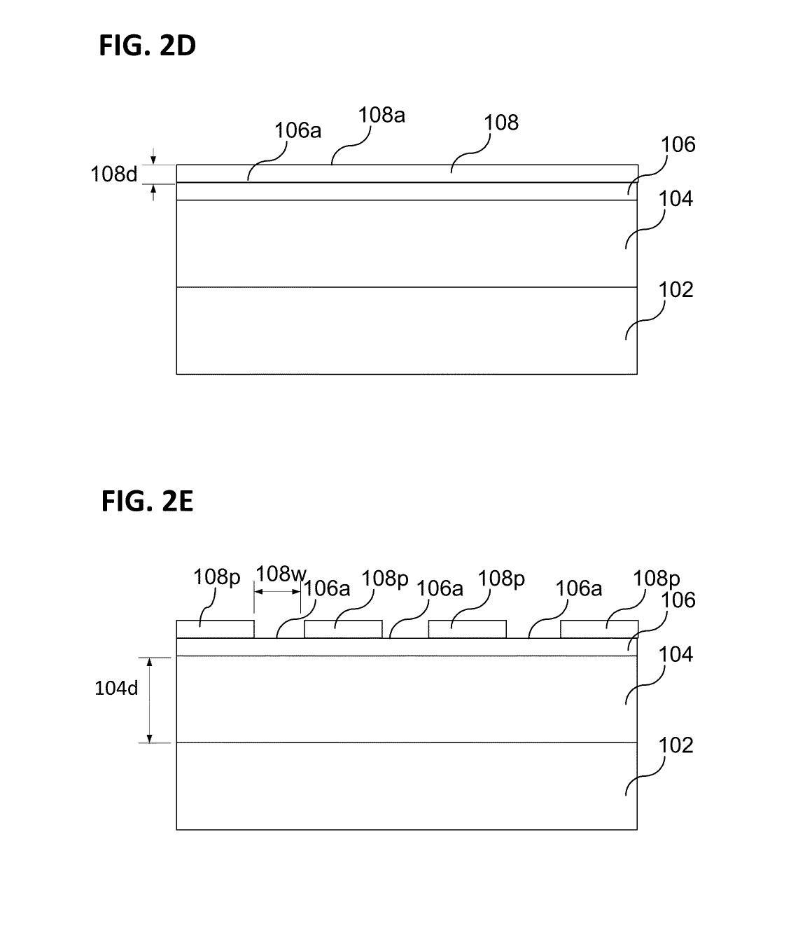

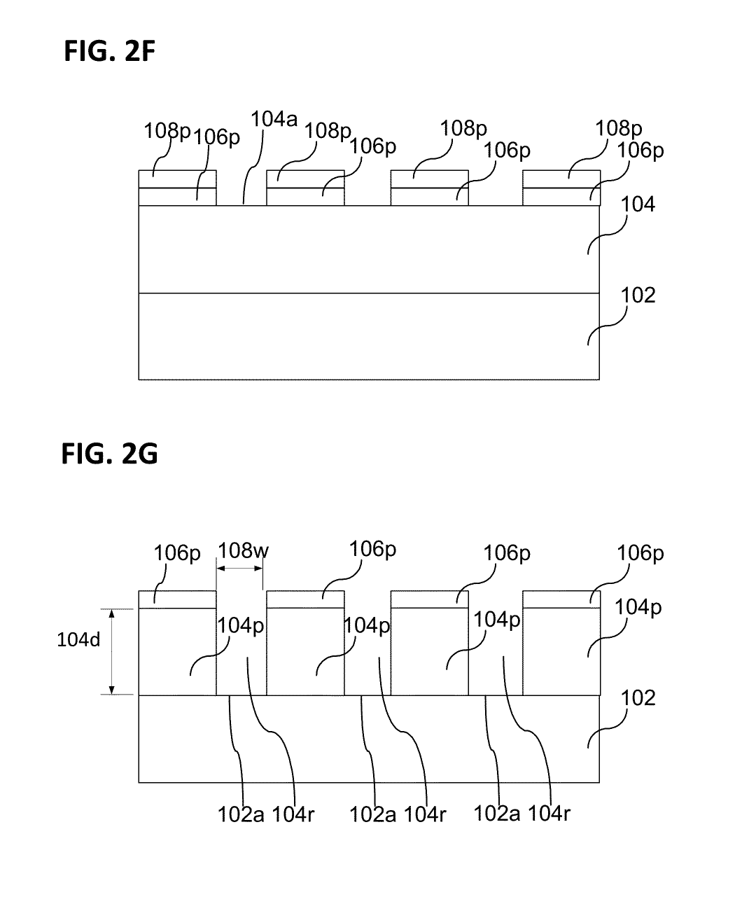

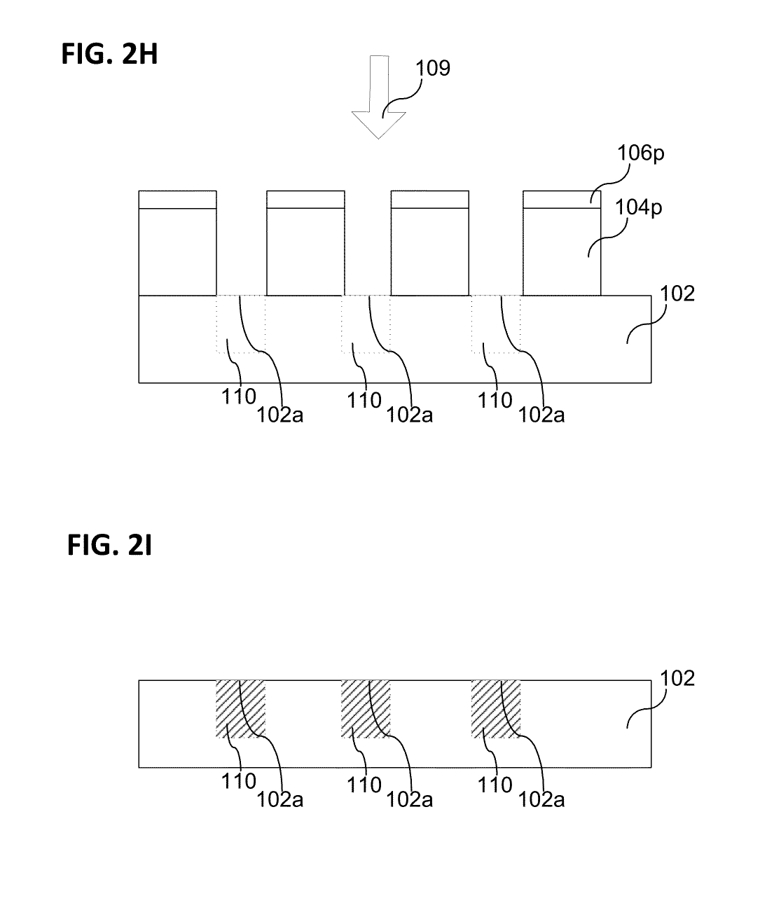

In FIGS. 2A to 2I a schematic side view or cross sectional view of a layer or carrier during the processing (e.g. during method S100a, S100b, S100c is carried out) is illustrated respectively, according to various embodiments.

FIG. 2A shows a carrier 102 or a layer 102 at an initial processing stage, according to various embodiments. The a carrier 102 may include a substrate, a wafer, a tape, a foil, and the like) and may be made of or may include semiconductor materials of various types, including silicon, germanium, Group III to V or other types, including polymers, for example, although in another embodiment, other suitable materials can also be used. The carrier 102 or layer 102 may be made of or may include silicon (e.g. doped or undoped), in an alternative embodiment, the carrier 102 or layer 102 may be a silicon on insulator (SOI) wafer. As an alternative, any other suitable semiconductor material may provide the carrier 102 or layer 102, for example semiconductor compound material such as gallium arsenide (GaAs), indium phosphide (InP), but also any suitable ternary semiconductor compound material or quaternary semiconductor compound material such as indium gallium arsenide (InGaAs). The carrier 102 or layer 102 may include a coated structure, e.g. a metal tape coated with silicon, and the like. The carrier 102 or layer 102 may further include a polymer, a laminate, or a metal. A carrier may further include a polymer foil, glass (e.g. silicon oxide based glass), or another suitable carrier being processable in semiconductor technology. The carrier 102 or layer 102 may be a layer stack or may include a plurality of various regions including various materials.

According to various embodiments, the layer 102 may be a surface layer of a carrier or a layer being formed (e.g. deposited) over a wafer. According to various embodiments, the layer 102 may be formed during a process used in semiconductor technology to manufacture an electronic device or an electronic component.

The carrier 102 or layer 102 may include at least one surface 102a. The at least one surface 102a may be the main processing surface of a carrier or wafer during processing in semiconductor technology.

As shown in FIG. 2B, a carbon layer 104 may be formed over the carrier 102 or over the layer 102, according to various embodiments. The carbon layer 104 may be formed over the surface 102a of the carrier 102 or over the surface 102a the layer 102, e.g. directly on the surface 102a or with one or more additional layer (e.g. buffer layers) between the carbon layer 104 and the carrier 102 or between the carbon layer 104 and the layer 102. According to various embodiments, the carbon layer 104 may also be referred to as carbon mask, carbon mask layer, carbon hard mask, or carbon hard mask layer.

According to various embodiments, a carbon layer 104 may also be referred to as carbon film or carbon thin film, wherein the carbon layer 104 may include a coating which may consist predominantly of the chemical element carbon, which include plasma polymer carbon layers, amorphous carbon layers, diamond-like carbon (DLC), CVD diamond layers and/or graphite layers. According to various embodiments, the carbon layer 104 may include a mixture of different types of carbon modifications.

According to various embodiments, the carbon layer 104 may include at least one of the following materials: hydrogen-free amorphous carbon (a-C); tetrahedral hydrogen-free amorphous carbon (ta-C); metalliferous (metal-containing) hydrogen-free amorphous carbon (a-C:Me), wherein Me may be iron (Fe), terbium (Er), gadolinium (Gd), titanium (Ti), and the like; hydrogenous (hydrogen containing or hydrogenated) amorphous carbon (a-C:H); tetrahedral hydrogenous amorphous carbon (ta-C:H); metalliferous (metal-containing) hydrogenous amorphous carbon (a-C:H:Me); modified (e.g. doped) hydrogenous amorphous carbon (a-C:H:X), wherein X may be at least one of Si, O, N, F, Sb, S, and/or B.

According to various embodiments, a-C may include mainly sp²-hybridized carbon, e.g. similar to graphite. Further, ta-C may include mainly sp^{a}-hybridized carbon, e.g. similar to diamond.

According to various embodiments, a-C:Me and a-C:H:Me may include a metal, wherein the mass density of the carbon layer including a-C:Me and/or a-C:H:Me may be larger than the mass density of carbon layers including for example a-C, ta-C, and/or a-C:H. Therefore, a carbon layer 104 including a-C:Me and/or a-C:H:Me may have enhanced ion-stopping properties which may allow a smaller film thickness for the carbon mask layer during ion implantation. Doping a-C or a-C:H with a metal may result in a compound based on a a-C-matrix or a-C:H-matrix and metal carbide.

According to various embodiments, a-C:H may include mainly sp²-hybridized carbon, e.g. similar to graphite. Further, ta-C:H may include mainly sp^{a}-hybridized carbon, e.g. similar to diamond. Further, a-C:H may include a hydrogen content (substance amount fraction) of larger than about 35%. According to various embodiments, ta-C:H may include a hydrogen content (substance amount fraction) of larger than about 25%.

According to various embodiments, a-C:H:X (X═Si, O, N, F, S, Sb, As, and/or B) may include amorphous carbon being doped with at least one additional material.

According to various embodiments, the carbon of the carbon layer 104 may be an amorphous solid, or a so-called quasi amorphous solid, or a glass-like solid.

According to various embodiments, the carbon layer 104 may further include graphite or graphite-like carbon and/or diamond or diamond-like carbon.

According to various embodiments, the carbon layer 104 may have a thickness 104d in the range from about 1 μm to about 10 μm, e.g. in the range from about 2 μm to about 10 μm, e.g. in the range from about 3 μm to about 8 μm. According to various embodiments, the carbon layer 104 may have a thickness 104d larger than about 3 μm, e.g. larger than about 4 μm, e.g. larger than about 5 μm, e.g. larger than about 6 μm, e.g. larger than about 7 μm, e.g. larger than about 8 μm, e.g. larger than about 9 μm, or even for example larger than about 10 μm. According to various embodiments, the carbon layer thickness 104d may not be limited as it would be for a resist.

According to various embodiments, for carrying out a ion implantation of phosphorus being accelerated having a kinetic energy of about 5 MeV (e.g. in the range from about 4 MeV to about 6 MeV), the carbon layer 104 may have a thickness 104d of about 5 μm (e.g. in the range from about 4 μm to about 6 μm) or larger than about 5 μm.

As illustrated in FIG. 2C, an additional hard mask layer 106 (a hard mask layer 106) may be deposited over the carbon layer 104, wherein the additional hard mask layer 106 may serve to pattern the carbon layer 104. The additional hard mask layer 106 may include for example a-Si, e.g. if the carrier 102 or layer 102 may include a silicon oxide surface layer. Illustratively, the additional hard mask layer 106 may be chosen to be selectively removable (e.g. via a selective etch process) with respect to the carrier 102 or layer 102.

According to various embodiments, the additional hard mask layer 106 may have a thickness 106d in the range from about 10 nm to about 1 μm, e.g. in the range from about 20 nm to about 500 nm, e.g. in the range from about 20 nm to about 100 nm. According to various embodiments, the thickness 106d of the additional hard mask layer 106 may be smaller than the thickness 104d of the carbon layer 104, e.g. many times smaller, e.g. less than half as thick.

As illustrated in FIG. 2D, a resist layer 108 or a soft mask layer 108 may be formed over the additional hard mask layer 106, wherein the resist layer 108 or the soft mask layer 108 may serve to pattern the additional hard mask layer 106. Illustratively, the additional hard mask layer 106 may be patterned using a standard lithographic process followed by an etch process, as described referring to FIG. 2E.

According to various embodiments, the resist layer 108 or the soft mask layer 108 may be applied over the surface 106a of the additional hard mask layer 106, e.g. homogeneously. Applying the resist of the resist layer 108 or the soft mask layer 108 may include spin coating or spray coating to generate a thin layer of the resist. Afterwards, the resist may be for example prebaked to drive off excess resist solvent, according to various embodiments. Several types of resists (e.g. a photoresist) may be used adapted to the process of exposing the resist to achieve desired results. Positive photoresists (e.g. DNQ-Novolac, PMMA, PMIPK, PBS, and the like) may be used, and/or negative photoresists (e.g. SU-8, poly isoprene, COP, and the like) may be used.

According to various embodiments, a variety of lithographic processes may be applied for patterning the resist layer 108 or the soft mask layer 108, as for example photolithography, microlithography or nanolithography, electron beam lithography, X-ray lithography, extreme ultraviolet lithography (EUV or EUVL), interference lithography, and the like.

According to various embodiments, before the resist layer 108 or the soft mask layer 108 may be formed over the surface 106a of the additional hard mask layer 106, the surface 106a may be cleaned via applying a cleaning process. Further, an adhesion promoter may be disposed over the surface 106a of the additional hard mask layer 106 before the resist layer 108 or the soft mask layer 108 may be formed.

According to various embodiments, the resist layer 108 or the soft mask layer 108 may be exposed (e.g. to a pattern of light), and developed subsequently, e.g. using a chemical photoresist developer.

According to various embodiments, the resist layer 108 or the soft mask layer 108 may be exposed so that a desired pattern may be transferred to the resist, e.g. by using light or electrons, wherein the desired pattern may be defined by a lithographic mask (e.g. a glass carrier with a patterned chromium layer). The wavelength of the used light may range from the wavelength of the visible light to a smaller wavelength in the ultra violet range. The exposure may be performed using X-rays or electrons having even a shorter wavelength than ultra violet light. Projection exposure systems (steppers or scanners) may be used projecting the lithographic mask many times onto a surface including a resist to create the complete exposure pattern. According to various embodiments, the exposed resist layer 108 or the exposed soft mask layer 108 may be developed, thereby the exposed resist layer 108 or the exposed soft mask layer 108 may be partially removed, thereby generating a patterned resist layer remaining over the surface 106a of the additional hard mask layer 106, as illustrated in FIG. 2E.

According to various embodiments, a post exposure bake (a heat treatment, e.g. rapid thermal processing) may be carried out before the actual developing process may be performed. The developing process may include the use of a chemical solution (a so-called developer) as for example sodium hydroxide or tetramethylammonium hydroxide (TMAH, a metal ion free developer). According to various embodiments, the remaining patterned resist 108p may be solidified in a hard bake process (a heat treatment, e.g. rapid thermal processing), realizing a more durable protecting layer for later processes as for example wet chemical etching, or plasma etching (and the like).

It should be noted, that a lithographic process, including applying a resist, partially exposing the resist to light, and developing the exposed resist may be considered as a patterning process, wherein a patterned resist layer 108p (a soft mask, or a resist mask) may be generated.

According to various embodiments, the thin patterned resist layer 108p may define the features size 108w (the lateral critical dimension CD). Since the thickness 108d of the resist layer 108 or the soft mask layer 108 may be thin, e.g. smaller than about 1 μm, e.g. smaller than about 500 nm, for patterning only the additional hard mask layer 106 (not the carbon layer 104), the features size 108w may be smaller than about 300 nm. Illustratively, the features size 108w may not be primarily limited by the thickness 108d of the resist layer 108 or the soft mask layer 108.

Subsequently, the pattern may be transferred from the patterned resist layer 108p to the additional hard mask layer 106, e.g. using an etch process, creating a so-called hard mask 106p or patterned hard mask 106p, as illustrated in FIG. 2F. Thereby, the etchant may be selective to the additional hard mask layer 106 and the etching may be anisotropic. According to various embodiments, a dry etching (e.g. reactive ion etching (RIE)) may be used for partially removing or patterning the additional hard mask layer 106.

According to various embodiments, if the additional hard mask layer 106 may include for example silicon dioxide, hydrofluoric acid (HFaq) may be used as wet etchant and carbon tetra fluoride (or another fluorine containing gas, e.g. CHF₃) may be used as plasma etchant. According to various embodiments, if the additional hard mask layer 106 may include for example silicon (e.g. a-Si), potassium hydroxide (KOH) may be used as wet etchant and carbon tetra fluoride (or another fluorine containing gas, e.g. SiF₆) may be used as plasma etchant.

As illustrated in FIG. 2F, the patterned hard mask layer 106p (and the patterned soft mask layer 108p) may provide a masking structure for subsequently patterning the carbon layer 104. According to various embodiments, the surface 104a of the carbon layer 104 may be partially exposed after the additional hard mask layer 106 (e.g. the a-Si layer) may be patterned.

According to various embodiments, the carbon layer 104 may be removed (etched) selectively in a subsequently performed etch process to provide a patterned carbon layer 104p, as illustrated in FIG. 2G. Therefore, according to various embodiments, oxygen or carbon monoxide (CO) may be used for example as etchant or plasma etchant. According to various embodiments, patterning the carbon layer 104 may include carrying out an anisotropic etch process, e.g. RIE, plasma etching.

As shown in FIG. 2G, one or more (e.g. a plurality of) recesses 104r may be formed in the carbon layer 104, exposing the surface 102a of the carrier 102 or layer 102 partially. The recesses 104r may be defined by the patterned hard mask 106p and therefore by the soft mask 108p formed over the additional hard mask layer 106 before.

According to various embodiments, the recesses 104r may expose the part of the carrier 102 or layer 102 to be doped. The recesses 104r of the patterned carbon layer 104p may have an aspect ratio (height 104d/width 108w) in the range from about 3 to about 10, e.g. in the range from about 4 to about 8. Further, the carbon layer 104 may be patterned, wherein the recesses of the patterned carbon layer 104p may have an aspect ratio larger than about 3, e.g. larger than about 4, e.g. larger than about 5, e.g. larger than about 6.

According to various embodiments, as illustrated in FIG. 2H, an ion implantation 109 may be carried out. Thereby, the patterned carbon layer 104p may protect one or more regions of the carrier 102 or layer 102 from being doped or from being penetrated by the ions, wherein the exposed regions 110 of the carrier 102 or layer 102 may be doped or penetrated by the ions. The ions may be provided by an implanter. The incident direction 109 of the ions may be perpendicular to the surface 102a of the carrier 102 or layer 102, as shown in FIG.° 2H, or may deviate from being perpendicular, e.g. ±60°.

After the ion implantation has been carried out, the patterned hard mask 106p and the patterned carbon layer 104p may be removed chemically (via wet etching or dry etching), e.g. by using oxygen plasma.

According to various embodiments, a heat treatment may be applied after the ion implantation process has been carried out, e.g. the cure implantation damages or to activate the implanted dopant. The heating of the carrier 102 or layer 102 may be performed for example with direct contact, e.g. using a hot plate, or by radiation, e.g. using a laser or lamps. According to various embodiments, a rapid thermal processing (RTP) may be applied, which may be performed under vacuum conditions using a laser heater or lamp heater, wherein the carrier 102 or layer 102 may be heated up to several hundred degrees Celsius or up to about 1000° C. or even greater within a short time period, e.g. within several seconds (e.g. within 1 s to 10 s).

FIG. 2I illustrates a doped carrier 102 or a doped layer 102 after method S100a, S100b, S100c has been carried out, according to various embodiments. The carrier 102 or layer 102 may be a part of an electronic device 200 or electronic component 200. It goes without saying that the carrier 102 or layer 102 may include additional structures, structure elements, regions, recesses, and the like, which are not shown in the figures. The one or more doped regions in the carrier may be a part of a power electronic device, e.g. of a power MOSFET or a power IGBT.

According to various embodiments, the doped regions 110 may have a depth 110d in the range from about several hundreds of nanometers to about several micrometers. According to various embodiments, the width of the doped regions 110 may be defined by the patterned carbon layer 104p.

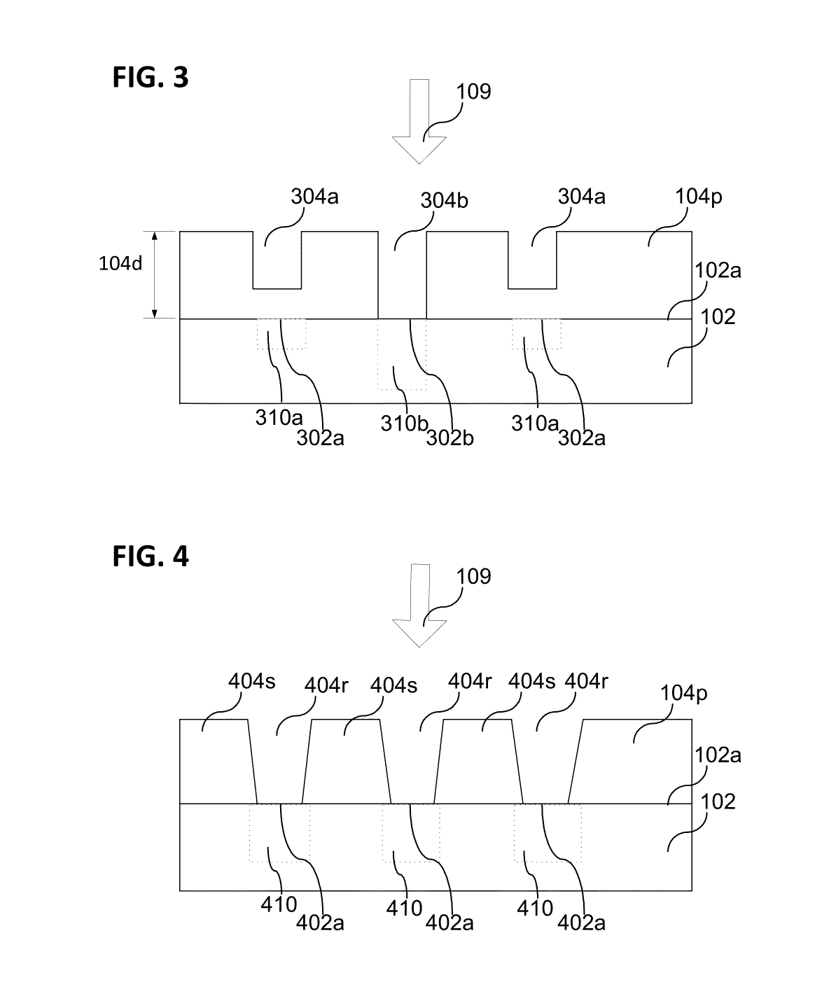

As shown in FIG. 3, a carbon mask layer 104p may be arranged over a carrier 102 or a layer 102, wherein the carbon mask layer 104p may at least partially cover the carrier 102 or layer 102. According to various embodiments, the carbon mask layer 104p may be generated by carrying out a layering process (e.g. a CVD or a PVD process), and by carrying out a patterning process subsequently, e.g. by using at least one of a hard mask material layer and a soft mask material layer, as described before. According to various embodiments, the carbon mask layer 104p may be a homogeneous layer of a carbon (e.g. a-C, a-C:H and the like). The thickness of the carbon mask layer 104p may be in a range from about several nanometers up to several micrometers. According to various embodiments, the thickness of the carbon mask layer 104p may depend on the type of carbon layer (e.g. a-C, a-C:H and the like) and the kinetic energy of the ions selected for the ion implantation process. According to various embodiments, the thickness of the carbon mask layer 104p may be in the range from about 1 μm to about 20 μm, e.g. in the range from about 3 μm to about 10 μm.

According to various embodiments, the thickness of the carbon mask layer 104p may be adapted to the energy of the ions provided during the ion implantation process. According to various embodiments, the carbon mask layer 104p may have a thickness which may be smaller than the average implantation depth (also referred to as projected range) of the used ions having a specific selected kinetic energy. That means that ions having a respectively selected kinetic energy, e.g. up to several MeV, or a kinetic energy in the range of about 1 MeV to about 5 MeV, may penetrate at least in the average through the carbon mask layer 104p, according to various embodiments.

According to another embodiment, the carbon mask layer 104p may have a thickness, which may be larger than the average implantation depth of the ions having a specific selected kinetic energy. That means that ions having a respectively selected kinetic energy, e.g. a few MeV, or a kinetic energy in the range of about 1 MeV to about 5 MeV, may not penetrate at least in the average through the carbon mask layer 104p. According to another embodiment, the carbon mask layer 104p may have a much larger thickness than the average implantation depth of the ions having a specific kinetic energy. That means that ions having a respectively selected kinetic energy, e.g. in the range of about 1 MeV to about 5 MeV, may not be able to reach the carrier 102 or layer 102.

The carrier 102 may include semiconducting material, as described before. According to various embodiments, the carrier 102 may be a silicon wafer, e.g. a (001)-oriented silicon wafer. According to various embodiments, the carrier 102 may include at least a silicon surface layer. According to various embodiments, carrier 102 may include at least a silicon oxide surface layer. According to various embodiments, the carrier may include a base region of an arbitrary material (e.g. including at least one of a metal, an alloy, a membrane, a polymer, a compound material), wherein the base layer is covered with a surface layer including at least one of silicon, epitaxially grown silicon, polysilicon or any other semiconducting material. According to various embodiments, the surface region of the carrier 102 may include silicon, wherein the surface region may have a thickness in the range from about several nanometers to about several micrometers or even larger. In other words, the layer 102 may be a surface region of a carrier or of a wafer.

According to various embodiments, a desired doping profile may be provided in the carrier 102 or layer 102, which may enable the functionality of an electronic device fabricated at least one of over and in the carrier 102 or layer 102 for example in subsequently performed processes and/or in processes performed before method S100a, S100b, S100c is carried out.

It should be noted, according to various embodiments, that the shape of the carrier 102 may not be limiting to the method described herein. According to various embodiments, the carrier may include various structure elements, material layers and the like, as it may be desired for the specific design of the electronic device, which is intended to be fabricated using at least method S100a, S100b, S100c to provide the desired doping profile for the electronic device.

According to various embodiments, the carrier 102 or layer 102 may include at least one of a p-well region and an n-well region (or p-doped region and an n-doped region), and further, the carrier 102 or layer 102 may be a doped carrier a doped layer, e.g. at least one of n-doped and p-doped. According to various embodiments, the carrier 102 or layer 102 may include a transistor, e.g. a field effect transistor, e.g. a bipolar transistor. According to various embodiments, the carrier 102 or layer 102 may include at least a part of an integrated circuit or an electronic component of an integrated circuit, e.g. the carrier 102 or layer 102 may include at least a part of a high-voltage device, a sensor, e.g. a hall sensor, e.g. a strain sensor, a diode, an electrostatic discharge protection device, an electrostatic discharge protection diode, and the like, wherein, according to various embodiments, at least a part of the integrated circuit or electronic component may be formed using method S100a, S100b, S100c. According to various embodiments, at least a part of doped channel regions of an integrated circuit or of an electronic component may be formed using method S100a, S100b, S100c.

As illustrated in FIG. 3, the patterned carbon layer 104p may include one or more first recesses 304a having a depth smaller than the height 104d of the deposited carbon layer 104, and one or more second recesses extending (e.g. vertically) through the deposited carbon layer 104 exposing the surface 102a of the carrier 102 or of the layer 102 partially. According to various embodiments, the one or more first regions 310a in the carrier 102 or layer 102 corresponding to the one or more first recesses 304a may be doped via ion implantation 109, wherein the one or more first regions 310a may include a first doping profile. According to various embodiments, the one or more second regions 310b in the carrier 102 or layer 102 corresponding to the one or more second recesses 304b may be doped via ion implantation 109, wherein the one or more second regions 310b may include a second doping profile. Illustratively, the doping profile of the one or more doped regions 310a, 310b in the carrier 102 or in the layer 102 may be defined or influenced by the specific pattern used for the carbon mask 104p. The ions may penetrated the carrier 102 or layer 102 through the surface regions 302a, 302b of the surface 102a of the carrier 102 or layer 102 thereby implanting an implant material into the regions 310a, 310b of the carrier 102 or layer 102.

As illustrated in FIG. 4, the carbon layer 104 may be patterned such that one or more recesses 404r may be formed within the deposited carbon layer 104, the one or more recesses 404r may extend through the carbon layer 104 exposing one or more surface regions 402a of the surface 102a of the carrier 102 or layer 102. According to various embodiments, the sidewalls of the one or more recesses 404r may be tilted, as illustrated in FIG. 4. The one or more recesses 404r may have a trapezoid shape. This may define or influence the doping profile of the one or more doped regions 410.

According to various embodiments, the term doping, as described herein, may include introducing an implant material into the carrier 102 or into the layer 102.

According to various embodiments, a patterned carbon layer 104p or a carbon mask 104p may be provided by forming a plurality of structure elements 404s over the carrier 102 or layer 102, the structure elements 404s of the plurality of structure elements 404s may include carbon, as described for the carbon layer 104. The structure elements 404s of the plurality of structure elements 404s may partially cover the surface 102a of the carrier 102 or layer 102, thereby preventing the ions provided in an ion implantation process partially from penetrating the carrier 102 or layer 102. Illustratively, the ions may stop within the structure elements 404s of the plurality of structure elements 404s.

According to various embodiments, depending on the specific design of the carrier 102 or layer 102 or the electronic component to be processed or manufactured, the carbon layer 104 may be removed from the carrier 102 or layer 102 or may remain on the carrier 102 or layer 102.

FIG. 5 illustrates a carrier or a layer which has been subjected to a high energy ion implantation (5 MeV), wherein the carrier or the layer was masked with a standard resist mask 501 having a thickness of about 6.5 μm. Due to the thickness of the resist, the type of masking material (resist) and the energy input from the ion beam, the resist mask 501 peeled off from the surface of the carrier (or may be deformed or may crack) during a high energy ion implantation. Further, the thickness of the standard resist mask 501 may limit the lateral resolution (critical dimension) due to the limited maximal processable aspect ratio of about 3.

FIG. 6 illustrates a carrier 102 or a layer 102 which has been subjected to a high energy ion implantation (5 MeV), wherein the carrier 102 or layer 102 was masked with a patterned carbon layer 104 (e.g. including a-C:H:M), as described herein. According to various embodiments, it was recognized, that a carbon layer 104, as described herein, does not peel off from the surface 102a of the carrier 102 or layer 102 during a high energy ion implantation 109. The adhesion properties of the carbon layer 104 on the carrier 102 or layer 102 may allow a high energy ion implantation while carbon layer 104 has a sufficient large thickness to block the ions. The carbon layer 104 may be deposited over the surface 102a of the carrier 102 or layer 102 via a PECVD process. Further, a buffer layer or adhesion promoter layer may be disposed between the surface 102a of the carrier 102 or layer 102 and the carbon layer 104 if desired. Further, the carbon layer 104 may have enhanced ion stopping properties (e.g. a higher density) compared to commonly used standard resists.

Further, it was recognized, that the ions of the ion beam may cause less stress or strain in the carbon layer 104 compared to commonly used standard resists. Therefore, the carbon layer 104 may remain substantially unchanged during a high energy ion implantation.

Further, the patterning of the carbon layer 104 may allow a higher aspect ratio, and therefore, structures with a smaller features size may be formed using a patterned carbon layer 104 as implantation mask.

According to various embodiments, a method for processing a layer may be provided, the method including: providing a patterned carbon layer 104p over a layer 102; and carrying out an ion implantation 109 through the patterned carbon layer 104p into the layer 102. According to various embodiments, a method for processing a layer may be provided, the method including: providing a patterned carbon layer 104p over a carrier 102; and carrying out an ion implantation 109 through the patterned carbon layer 104p into the carrier 102.

According to various embodiments, providing the patterned carbon layer 104p may include forming a carbon layer 104 over the layer 102 and then patterning the carbon layer 104. According to various embodiments, providing the patterned carbon layer 104p may include forming a carbon layer 104 over the carrier 102 and then patterning the carbon layer 104.

According to various embodiments, patterning the carbon layer 104 may include forming a patterned hard mask layer 106p over the carbon layer 104 and performing an anisotropic etch process to partially remove the carbon layer 104. According to various embodiments, the anisotropic etch process may include dry etching using oxygen.

According to various embodiments, forming the patterned hard mask layer 106p may include forming a hard mask layer 106 including amorphous silicon and patterning the amorphous silicon hard mask layer 106.

According to various embodiments, patterning the amorphous silicon hard mask layer 106 may include carrying out a lithographic process and an etch process.

According to various embodiments, at least a part of the patterned carbon layer 104p may have a thickness 104d of equal to or larger than 3 μm. According to various embodiments, at least a part of the patterned carbon layer 104p may have a thickness 104d of equal to or larger than 4 μm. According to various embodiments, at least a part of the patterned carbon layer 104p may have a thickness 104d of equal to or larger than 5 μm. According to various embodiments, at least a part of the patterned carbon layer 104p may have a thickness 104d of equal to or larger than 6 μm. According to various embodiments, at least a part of the patterned carbon layer 104p may have a thickness 104d of equal to or larger than 7 μm.

According to various embodiments, the patterned carbon layer 104p may include at least one recess 104r having an aspect ratio of equal to or larger than 4. According to various embodiments, the patterned carbon layer 104p may include at least one recess 104r having an aspect ratio of equal to or larger than 5. According to various embodiments, the patterned carbon layer 104p may include at least one recess 104r having an aspect ratio of equal to or larger than 6.

According to various embodiments, the patterned carbon layer 104p may include amorphous carbon. According to various embodiments, the patterned carbon layer 104p may consist of amorphous carbon.

According to various embodiments, the patterned carbon layer may include hydrogenated amorphous carbon. According to various embodiments, the patterned carbon layer may consist of hydrogenated amorphous carbon.

According to various embodiments, the patterned carbon layer may be doped with a metal and/or modified with an additional material.

According to various embodiments, the method for processing a layer 102 may further include: removing the patterned carbon layer 104p after the ion implantation, e.g. via ashing. According to various embodiments, the method for processing a carrier 102 may further include: removing the patterned carbon layer 104p after the ion implantation, e.g. via ashing. According to various embodiments, the ashing may include a dry ashing via oxygen plasma.

According to various embodiments, the method for processing a layer 102 may further include: carrying out an anneal to condense the carbon layer 104 before the ion implantation is carried out. According to various embodiments, the method for processing a carrier 102 may further include: carrying out an anneal to condense the carbon layer 104 before the ion implantation is carried out. Thereby, according to various embodiments, the density of the deposited carbon layer 104 may be enlarged.

According to various embodiments, the method for processing a layer 102 or a carrier 102 may further include: carrying out an anneal after the ion implantation has been carried out. According to various embodiments, the anneal may include rapid thermal annealing. According to various embodiments, the anneal may at least one or activate the implanted material (doping) and curing implantation damage in the crystal structure of the material of the carrier 102 or layer 102.

According to various embodiments, during the ion implantation ions may be accelerated such that the ions may have a kinetic energy of equal to or larger than 1 MeV. According to various embodiments, during the ion implantation ions may be accelerated such that the ions may have a kinetic energy of equal to or larger than 2 MeV. According to various embodiments, during the ion implantation ions may be accelerated such that the ions may have a kinetic energy of equal to or larger than 3 MeV. According to various embodiments, during the ion implantation ions may be accelerated such that the ions may have a kinetic energy of equal to or larger than 4 MeV.

According to various embodiments, a method for manufacturing an electronic device may be provided, the method including: forming a carbon layer 104 over a layer 102; patterning the carbon layer 104 by partially removing the carbon layer 104; and performing an ion implantation 109 through the patterned carbon layer 104p into the layer 102. According to various embodiments, a method for manufacturing an electronic device may be provided, the method including: forming a carbon layer 104 over a carrier 102; patterning the carbon layer 104 by partially removing the carbon layer 104; and performing an ion implantation 109 through the patterned carbon layer 104p into the carrier 102.

According to various embodiments, the patterned carbon layer 104p may include a plurality of recesses 104r having a lateral extension 108w of equal to or smaller than 1 μm and a depth of equal to or larger than 4 μm. In other words, the recesses 104r may have an aspect ratio of equal to or larger than 4. According to various embodiments, the patterned carbon layer 104p may include a plurality of recesses 104r having a lateral extension 108w of equal to or smaller than 1 μm and a depth of equal to or larger than 5 μm. In other words, the recesses 104r may have an aspect ratio of equal to or larger than 5. According to various embodiments, the patterned carbon layer 104p may include a plurality of recesses 104r having a lateral extension 108w of equal to or smaller than 1 μm and a depth of equal to or larger than 6 μm. In other words, the recesses 104r may have an aspect ratio of equal to or larger than 6.

According to various embodiments, forming the carbon layer 104 may include applying at least one of physical vapor deposition (PVD) and chemical vapor deposition (CVD). According to various embodiments, physical vapor deposition may include at least one of sputtering, magnetron sputtering, high power pulsed magnetron sputtering, rf sputtering, cathodic arc deposition, pulsed laser deposition, molecular beam epitaxy, thermal evaporation, and the like. According to various embodiments, chemical vapor deposition (CVD) may include at least one of plasma enhanced CVD, low pressure CVD, atomic layer deposition, and the like.

According to various embodiments, the carbon layer 104 may be a non-conformal layer deposited over a plurality of structure elements on a layer 102 or carrier 102. This may enable an easier removing of the carbon layer 104 after the ion implantation has been carried out, since recesses between the structure elements of the plurality of structure elements may not be filled with carbon.

According to various embodiments, patterning the carbon layer 104 may include: forming an (additional) hard mask material layer 106 over the carbon layer 104; patterning the (additional) hard mask material layer 106 to define regions in the carbon layer 104 to be removed; and removing the regions in the carbon layer 104 defined by the patterned hard mask material layer 106p. According to various embodiments, the (additional) hard mask material layer 106 may include amorphous silicon. According to various embodiments, amorphous silicon may enable providing a hard mask over the carbon layer 104 without damaging the carbon layer 104, e.g. since the amorphous silicon may be deposited a low temperatures, e.g. smaller than about 400° C.

According to various embodiments, patterning the (additional) hard mask material layer 106 may include: forming a resist layer 108 over the (additional) hard mask material layer 106; patterning the resist layer 108 to define regions in the (additional) hard mask material layer 106 to be removed; and removing the regions in the (additional) hard mask material layer 106 defined by the patterned resist layer 108p.

According to various embodiments, a method may be provided, the method may include: providing one or more structure elements over a layer 102, the one or more structure elements including carbon or amorphous carbon, the one or more structure elements providing a masking structure 104p for an ion implantation process 109; and carrying out an ion implantation process 109 to partially dope the layer 102, wherein the one or more structure elements protect one or more regions in the layer 102 from being doped. According to various embodiments, a method may be provided, the method may include: providing one or more structure elements over a carrier 102, the one or more structure elements including carbon or amorphous carbon, the one or more structure elements providing a masking structure 104p for an ion implantation process 109; and carrying out an ion implantation process 109 to partially dope the carrier 102, wherein the one or more structure elements protect one or more regions in the carrier 102 from being doped.

According to various embodiments, the masking structure 104p may include a plurality of recesses (e.g. between the one or more structure elements) having a lateral extension of equal to or smaller than 1 μm and a depth of equal to or larger than 4 μm. In other words, the masking structure 104p may allow a patterning with a high aspect ratio, e.g. larger than 4.

According to various embodiments, a patterning may include a double patterning. According to various embodiments, patterning may include photolithography as used in semiconductor industry to pattern parts of a thin film 102 or the bulk of a substrate 102. According to various embodiments, a patterned layer (e.g. a patterned carbon layer 104p) may include a geometric pattern. According to various embodiments, a resist may include a polymer, wherein the polymer may not have an amorphous structure or a glass structure. In other words, a resist or photoresist may not be regarded as a carbon layer 104.

According to various embodiments, the carbon layer 104 may not be light-sensitive such that the carbon layer 104 has to be patterned via an additional mask.

According to various embodiments, the layer 102 may be a carrier or a wafer.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for processing a layer, the method comprising:
providing a patterned carbon layer over a layer; and
carrying out an ion implantation through the patterned carbon layer into the layer.

2. The method according to claim 1,
wherein providing the patterned carbon layer comprises forming a carbon layer over the layer and then patterning the carbon layer.

3. The method according to claim 2,
wherein patterning the carbon layer comprises forming a patterned hard mask layer over the carbon layer and then performing an anisotropic etch process to partially remove the carbon layer.

4. The method according to claim 3,
wherein forming the patterned hard mask layer comprises forming a hard mask layer comprising amorphous silicon and then patterning the amorphous silicon hard mask layer.

5. The method according to claim 1,
wherein at least a part of the patterned carbon layer has a thickness of equal to or larger than 3 μm.

6. The method according to claim 1,
wherein the patterned carbon layer comprises at least one recess having an aspect ratio of equal to or larger than 4.

7. The method according to claim 1,
wherein the patterned carbon layer comprises amorphous carbon.

8. The method according to claim 1,
wherein the patterned carbon layer comprises hydrogenated carbon.

9. The method according to claim 1, further comprising:
removing the patterned carbon layer via ashing after the ion implantation has been carried out.

10. The method according to claim 9,
wherein the ashing comprises a dry ashing via oxygen plasma.

11. The method according to claim 1, further comprising:
carrying out an anneal to condense the carbon layer before the ion implantation is carried out.

12. The method according to claim 1, further comprising:
carrying out an anneal after the ion implantation has been carried out.

13. The method according to claim 1,
wherein the ions during the ion implantation are accelerated to have a kinetic energy of equal to or larger than 1 MeV.

14. A method for manufacturing an electronic device, the method comprising:
forming a carbon layer over a layer;
patterning the carbon layer by partially removing the carbon layer; and
performing an ion implantation through the patterned carbon layer into the layer.

15. The method according to claim 14,
wherein the patterned carbon layer comprises one or more recesses having a lateral extension of equal to or smaller than 1 μm and a depth of equal to or larger than 4 μm.

16. The method according to claim 14,
wherein forming the carbon layer comprises applying at least one of physical vapor deposition and chemical vapor deposition.

17. The method according to claim 14,
wherein patterning the carbon layer comprises:
forming a hard mask material layer over the carbon layer;
patterning the hard mask material layer to define regions in the carbon layer to be removed; and
removing the regions in the carbon layer defined by the patterned hard mask material layer.

18. The method according to claim 17,
wherein patterning the hard mask material layer comprises:
forming a resist layer over the hard mask material layer;
patterning the resist layer to define regions in the hard mask material layer to be removed; and
removing the regions in the hard mask material layer defined by the patterned resist layer.

19. A method, comprising:
providing one or more structure elements over a carrier, the one or more structure elements comprising carbon, the one or more structure elements providing a masking structure for an ion implantation process;
carrying out an ion implantation process to partially dope the carrier, wherein the one or more structure elements protect one or more regions in the carrier from being doped.

20. The method according to claim 19,
wherein the masking structure comprises a plurality of recesses having a lateral extension of equal to or smaller than 1 μm and a depth of equal to or larger than 4 μm.
